(19) United States
(12) Patent Application Publication
(10) Pub. No.: US 2025/0286010 A1
(43) Pub. Date: Sep. 11, 2025

(54) SEMICONDUCTOR MODULE AND VEHICLE

(71) Applicant: FUJI ELECTRIC CO., LTD., Kawasaki-shi (JP)

(72) Inventor: Ryo MARUYAMA, Kawasaki-shi (JP)

(73) Assignee: FUJI ELECTRIC CO., LTD., Kawasaki-shi (JP)

(21) Appl. No.: 19/041,322

(22) Filed: Jan. 30, 2025

(30) Foreign Application Priority Data
Mar. 11, 2024 (JP) 2024-036955

(51) Int. Cl. H01L 23/00; H01L 23/373; H01L 23/538; H01L 25/07

(52) U.S. Cl. CPC H01L 24/37; H01L 24/40; H01L 24/73; H01L 25/072; H01L 23/3736; H01L 23/538; H01L 24/32; H01L 24/48; H01L 2224/32227; H01L 2224/37011; H01L 2224/37012; H01L 2224/37033; H01L 2224/40137; H01L 2224/40227; H01L 2224/40491; H01L 2224/48227; H01L 2224/73221; H01L 2224/73263; H01L 2224/73265

(57) ABSTRACT

A semiconductor module includes a wiring board, a semiconductor element disposed on and electrically connected to a conductor pattern of the wiring board, and a wiring member electrically connecting a conductor to an electrode of the semiconductor element. The wiring member includes a first conductor spacer, a second conductor spacer, and a laminate connecting the conductor spacers to each other. The laminate includes a plurality of conductor foils that are disposed in a laminated manner. The plurality of conductor foils includes at least one intermediate conductor foil, and first and second conductor foils sandwiching the intermediate conductor foil interposed therebetween. The intermediate conductor foil includes a void formation area in which a void is formed in the thickness direction between the linking region of the first conductor foil and the linking region of the second conductor foil.

### CROSS-REFERENCE TO RELATED APPLICATION

This application is based upon and claims the benefit of priority to Japanese Patent Application No. 2024-036955, filed on Mar. 11, 2024, the entire contents of which are incorporated herein by reference.

### BACKGROUND OF THE INVENTION

### 1. Technical Field

The present invention relates to a semiconductor module and a vehicle.

### 2. Description of the Related Art

Among semiconductor modules in which a semiconductor element is sealed with an insulating material, there is a semiconductor module including a plate-shaped wiring member called a lead (for example, JP 2018-61066 A, WO 2018/142863 A, JP 2003-188328 A, WO 2020/255663 A, JP 2021-108369 A, JP H09-115965 A, JP H07-288269 A, US 2008-0,246,130 A, and JP 2016-92346 A). The lead is used for connecting an electrode of a semiconductor element and an electrode of another semiconductor element or another conductive member. The lead is bonded to a conductor such as an electrode of a semiconductor element by using a bonding material such as solder.

### SUMMARY OF THE INVENTION

When a lead is connected to a conductor to be connected such as an electrode of a semiconductor element by using a bonding material, a shape of the bonding material for each semiconductor module may vary due to a deviation in a relative position between the lead and the conductor in a bonding process. The variation in the shape of a bonding material may cause a decrease in the reliability of a semiconductor module.

One object of the present invention is to improve the reliability of a semiconductor module using a lead as a wiring member that connects an electrode of a semiconductor element and another conductor.

A semiconductor module according to one aspect includes a wiring board including an insulating substrate and a conductor pattern being disposed on a first surface of the insulating substrate, a semiconductor element being disposed on the conductor pattern of the wiring board, the semiconductor element being connected to the conductor pattern, and a wiring member being configured to electrically connect another conductor and an electrode that is provided on a surface of the semiconductor element, the surface being opposite the conductor pattern. The wiring member includes a first conductor spacer being bonded to the electrode of the semiconductor element, a second conductor spacer being bonded to the other conductor, and a laminate including a plurality of conductor foils being configured to connect the first conductor spacer and the second conductor spacer, the plurality of conductor foils being disposed in a laminated manner at different distances from the surface of the semiconductor element on which the electrode is formed. Each of the plurality of conductor foils of the laminate includes a first connection region serving as a connection region with the first conductor spacer, a second connection region serving as a connection region with the second conductor spacer, and a linking region between the first connection region and the second connection region. The plurality of conductor foils includes at least one intermediate conductor foil and a first conductor foil and a second conductor foil being disposed in a laminated manner with the at least one intermediate conductor foil being interposed between the first conductor foil and the second conductor foil, and each of the at least one intermediate conductor foil includes a void formation portion that forms a void between the linking region of the first conductor foil and the linking region of the second conductor foil.

According to the above aspect, the reliability of a semiconductor module using a lead as a wiring member can be improved.

### BRIEF DESCRIPTION OF THE DRAWINGS

FIG. 1 is a plan view of a semiconductor module according to an embodiment;

FIG. 2 is a cross-sectional view taken along line A-A′ in FIG. 1;

FIG. 3 is an equivalent circuit diagram of an inverter circuit formed in the semiconductor module in FIG. 1;

FIG. 4 is an exploded perspective view for explaining a first configuration example of a wiring member;

FIG. 5A is a plan view of the wiring member illustrated in FIG. 4, and FIG. 5B is a cross-sectional view taken along line B-B′ in FIG. 5A;

FIG. 6A is a cross-sectional view for explaining a connecting process of connecting emitter electrodes of semiconductor elements with a wiring member, FIG. 6B is a cross-sectional view for explaining an example of warpage generated in a wiring board, and FIG. 6C is a cross-sectional view for explaining an example of warpage of the wiring member;

FIG. 7A is a plan view for explaining a second configuration example of the wiring member, and FIG. 7B is a cross-sectional view taken along line C-C′ in FIG. 7A;

FIG. 8 is an exploded perspective view for explaining a third configuration example of the wiring member;

FIG. 9A is a plan view of the wiring member illustrated in FIG. 8, and FIG. 9B is a cross-sectional view taken along line D-D′ in FIG. 9A;

FIG. 10A is a plan view for explaining a fourth configuration example of the wiring member, and FIG. 10B is a view of the wiring member as viewed in the direction of arrow E in FIG. 10A;

FIG. 11A is a front view for explaining a fifth configuration example of the wiring member, and FIG. 11B is a front view for explaining a sixth configuration example of the wiring member;

FIG. 12A is a front view for explaining a seventh configuration example of the wiring member, and FIG. 12B is a plan view for explaining an eighth configuration example of the wiring member; and

FIG. 13 is a schematic plan view for illustrating an example of a vehicle to which the semiconductor module according to the embodiment is applied.

### DETAILED DESCRIPTION

Hereinafter, embodiments of the present invention will be described in detail with reference to the drawings. A “semiconductor module” in the following description is obtained by sealing semiconductor elements, which are referred to as semiconductor chips, dies, or the like, with an insulating material. The semiconductor module may be referred to as a “semiconductor device” or the like.

An X axis, a Y axis, and a Z axis in the drawings are illustrated for the purpose of defining a plane and a direction in the illustrated semiconductor module and the like. The X axis, the Y axis, and the Z axis are perpendicular to each other and form a right-handed system. In the following description, a direction parallel to the X axis is referred to as an X direction, a direction parallel to the Y axis is referred to as a Y direction, and a direction parallel to the Z axis is referred to as a Z direction. Also, in a case where each of the X direction, the Y direction, and the Z direction is associated with a direction of an arrow (positive or negative) of a corresponding one of the X axis, the Y axis, and the Z axis illustrated, a “positive side” or a “negative side” is added.

In the present specification, the Z direction may be referred to as a vertical direction and a laminating direction. In the present specification, “on” and “upper side” are intended to be on the positive side in the Z direction with respect to the reference surface, member, position, and the like, and “below” and “lower side” are intended to be on the negative side in the Z direction with respect to the reference surface, member, position, and the like. For example, when it is described that “the member B is disposed on the member A”, the member B is disposed on the positive side in the Z direction as viewed from the member A. Also, when the term “upper surface of the member A” is described, the surface includes a surface that is positioned at the end of the member A on the positive side in the Z direction and faces the positive side in the Z direction. These directions and surfaces associated with the directions are words used for convenience of description, and a correspondence relationship with the directions of the X axis, the Y axis, and the Z axis may change depending on the mounting orientation of the semiconductor module and the like. For example, in the present specification, a surface of a semiconductor element facing a wiring board is referred to as a lower surface, and a surface opposite to the lower surface is referred to as an upper surface, but the terms are not limited thereto, and the surface facing the wiring board may be referred to as the upper surface, and the surface opposite thereto may be referred to as the lower surface.

An aspect ratio and a magnitude relationship between respective members in each drawing are merely schematically represented, and do not necessarily coincide with a relationship in a semiconductor module actually manufactured. For convenience of description, it is also assumed that a magnitude relationship between respective members is exaggeratedly expressed, or an expression is different from an outer shape of a member used in an actual semiconductor module. In addition, for convenience of description, some of the cross-sectional views illustrate a cross-sectional configuration of the semiconductor module cut along a virtual cutting line that cannot be accurately illustrated in plan view.

The descriptions of “not illustrated” and the like in the present specification are intended not to clearly indicate, by use of a specific reference sign and a leader line, which portion of the drawings is a component to which the descriptions are given. For example, a “first main electrode (not illustrated)” is intended to mean both that a portion representing the first main electrode (for example, a shape and a line) is not illustrated in the drawings, and that there is neither a reference sign nor a leader line clearly indicating a portion corresponding to the first main electrode in the drawings. Also, the underlined reference sign in the drawings indicates a reference sign for a whole component that encompasses a plurality of portions distinguished by a plurality of reference signs.

A semiconductor module to be illustrated in the following description may be applied to, for example, a power conversion apparatus such as an inverter apparatus of industrial or electrical equipment (for example, an in-vehicle motor). Thus, in the following description, detailed description of the same or similar configuration, function, operation, manufacturing method, and the like as or to those of a known semiconductor module will be omitted.

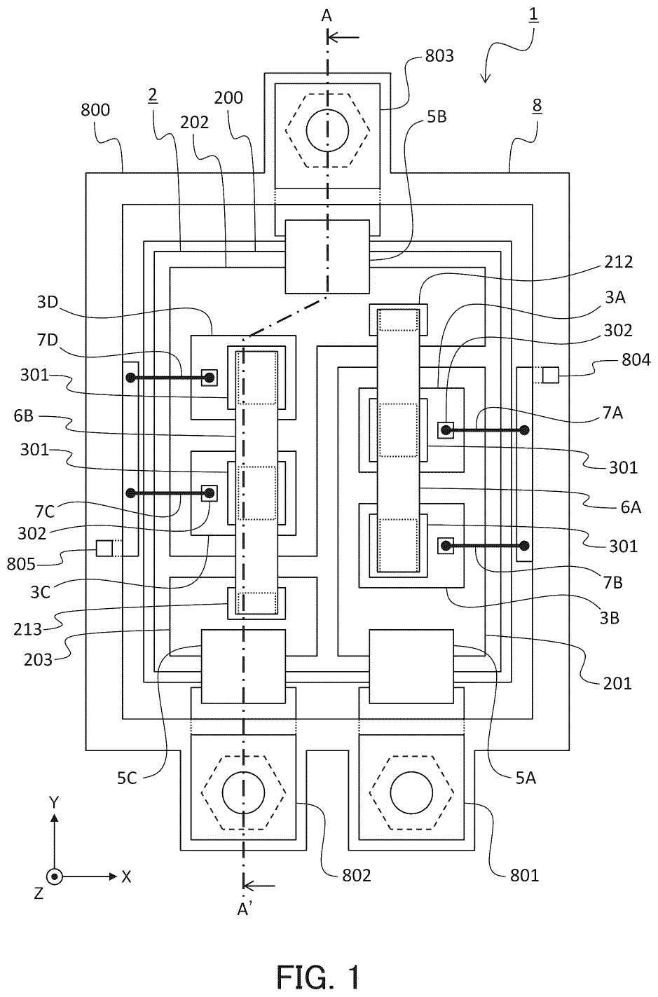

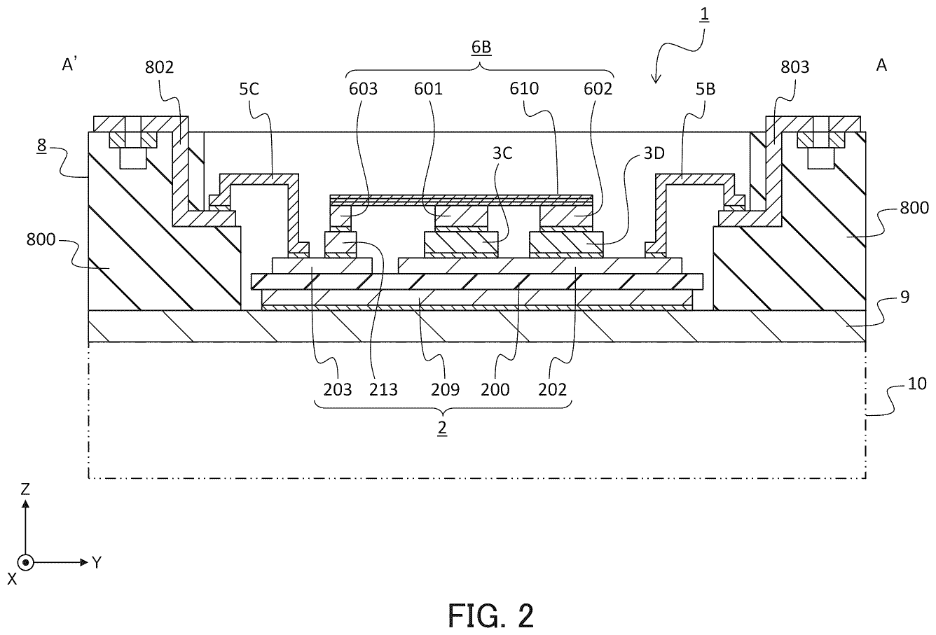

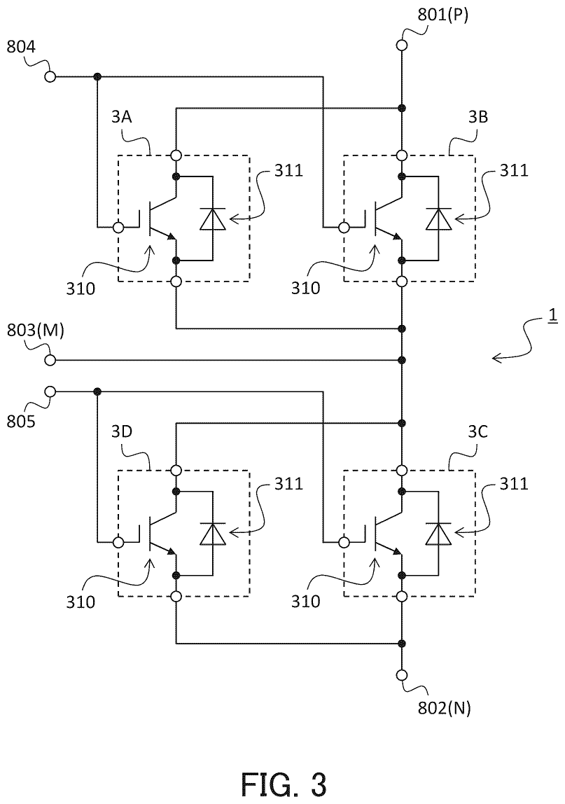

FIG. 1 is a plan view of a semiconductor module according to an embodiment. FIG. 2 is a cross-sectional view taken along line A-A′ in FIG. 1. FIG. 3 is an equivalent circuit diagram of an inverter circuit formed in the semiconductor module in FIG. 1.

A semiconductor module 1 illustrated in FIGS. 1 and 2 includes a wiring board 2, semiconductor elements 3A to 3D, leads 5A to 5C, wiring members 6A and 6B, bonding wires 7A to 7D, a case 8, a sealing material (not illustrated), and a heat dissipation plate 9. In the present specification, in a case where a plurality of identical components are distinguished from each other, a reference sign represented by combination of a number and an alphabet following the number is described, and in a case where a plurality of identical components are not distinguished from each other, a reference sign represented by only the number is described. For example, when a specific semiconductor element among the four semiconductor elements 3A to 3D is designated, the reference sign (any one of 3A to 3D) assigned to the specific semiconductor element is described in the drawings, and in other cases, the semiconductor element is simply described as “semiconductor element 3”.

The wiring board 2 is an element mounting component on which the semiconductor element 3 is mounted. For example, as illustrated in FIG. 3, the semiconductor element 3 includes a switching element 310 and a diode element 311 connected in anti-parallel with the switching element 310. The semiconductor element 3 may be, for example, a reverse conducting (RC)-insulated gate bipolar transistor (IGBT) element obtained by integrating an IGBT element, which is the switching element 310, with a function of a free wheeling diode (FWD) element, which is an example of the diode element 311.

The wiring board 2 includes an insulating substrate 200, conductor patterns 201 to 203 disposed on an upper surface of the insulating substrate 200, and a heat dissipation pattern 209 disposed on a lower surface of the insulating substrate 200. The wiring board 2 may be a direct copper bonding (DCB) substrate or an active metal brazing (AMB) substrate, but is not limited thereto.

The insulating substrate 200 may be, for example, a ceramic substrate made of a ceramic material such as aluminum oxide (Al₂O₃), aluminum nitride (AlN), silicon nitride (Si₃N₄), or a composite material of aluminum oxide (Al₂O₃) and zirconium oxide (ZrO₂). The insulating substrate 200 may be a substrate obtained by molding an insulating resin such as epoxy resin into a sheet shape, a substrate obtained by impregnating a base material such as a glass fiber with an insulating resin, a substrate obtained by coating a surface of a flat plate-shaped metal core with an insulating resin, or the like.

The conductor patterns 201 to 203 disposed on the upper surface of the insulating substrate 200 are used as a wiring member in an electronic circuit such as an inverter circuit formed in the semiconductor module 1. The heat dissipation pattern 209 disposed on the lower surface of the insulating substrate 200 is used as a thermally conductive material that conducts heat generated by the semiconductor element 3 during operation of the semiconductor module 1 to the heat dissipation plate 9. The conductor patterns 201 to 203 and the heat dissipation pattern 209 are each formed of, for example, a metal plate or a metal foil, either of which is made of copper or aluminum.

The wiring board 2 is disposed on the upper surface of the heat dissipation plate 9 together with the case 8. The case 8 includes a frame-shaped insulating member 800 having open ends on the upper surface and the lower surface thereof, and a plurality of terminals 801 to 805 integrated with the insulating member 800. When being disposed on the upper surface of the heat dissipation plate 9, the insulating member 800 of the case 8 may have a shape that defines a space capable of housing the wiring board 2, the semiconductor element 3, the lead 5, the wiring member 6, the bonding wire 7, and the like, and capable of being filled with a sealing material (insulating material) for sealing them. The heat dissipation plate 9 may be, for example, a metal plate made of copper or aluminum. The heat dissipation pattern 209 of the wiring board 2 is bonded to be in close contact with the upper surface of the heat dissipation plate 9 by using a bonding material such as solder (not illustrated) or a thermally conductive material such as thermal grease or thermal compound. A plurality of fins may be provided on the lower surface of the heat dissipation plate 9. The heat dissipation plate 9 may be a portion of a cooler 10 or a component bonded to the cooler 10. That is, the cooler 10 is an optional component in the semiconductor module 1 of the present embodiment.

The terminals 801 to 805 of the case 8 are broadly classified into main terminals 801 to 803 and control terminals 804 and 805. The main terminals 801 to 803 and the control terminals 804 and 805 each include: an inner terminal portion exposed to a space in which the wiring board 2, the semiconductor element 3, and the like are housed; and an outer terminal portion exposed to the outside of the semiconductor module 1.

The main terminals 801 to 803 are electrically connected to an electrode that causes a main current to flow through a switching element (for example, IGBT element) in the semiconductor element 3. In the case of the semiconductor module 1 in which the inverter circuit illustrated in FIG. 3 is formed, the first main terminal 801 is a P terminal that is connected to the positive electrode of a DC power supply and is for obtaining (outputting) an alternating current, and is electrically connected to the collector electrodes (not illustrated) of the semiconductor elements 3A and 3B disposed on the upper surface of the first conductor pattern 201 of the wiring board 2. The second main terminal 802 is an N terminal connected to the negative electrode of the DC power supply, and is electrically connected to emitter electrodes 301 of the semiconductor elements 3C and 3D disposed on the upper surface of the second conductor pattern 202 of the wiring board 2. The third main terminal 803 is an M terminal connected to a load consuming an alternating current converted from a direct current by the semiconductor module 1, and is electrically connected to an emitter electrode 301 of the semiconductor element 3 disposed on the upper surface of the first conductor pattern 201 and to the collector electrode (not illustrated) of the semiconductor element 3 disposed on the upper surface of the second conductor pattern 202.

The control terminal 804 is electrically connected to a gate electrode 302 of the semiconductor element 3 disposed on the upper surface of the first conductor pattern 201, and the control terminal 805 is connected to the gate electrode 302 of the semiconductor element 3 disposed on the upper surface of the second conductor pattern 202.

The case 8 may include an additional terminal different from the main terminals 801 to 803 and the control terminals 804 and 805. For example, the case 8 may include: a first additional control terminal electrically connected to the emitter electrode 301 of the semiconductor element 3 disposed on the upper surface of the first conductor pattern 201; and a second additional control terminal electrically connected to the emitter electrode 301 of the semiconductor element 3 disposed on the upper surface of the second conductor pattern 202. These additional control terminals are terminals for connecting the emitter electrode 301 of the semiconductor element 3 to a gate drive circuit (not illustrated) connected to the gate electrode 302 of the semiconductor element 3, and are referred to as an auxiliary emitter terminal, a sense emitter terminal, an emitter sense terminal, or the like. The gate drive circuit is a circuit that generates a control signal for controlling on/off of the switching element of the semiconductor element 3 using the emitter potential input through the additional control terminal as a ground, and applies the control signal to the gate electrode 302 of the semiconductor element 3.

Each of the semiconductor elements 3A and 3B disposed on the first conductor pattern 201 of the wiring board 2 includes a collector electrode (not illustrated) on the lower surface, and the collector electrode is bonded to the first conductor pattern 201 by using a bonding material (not illustrated) such as solder. The first conductor pattern 201 is electrically connected to the first main terminal 801 via the first lead 5A. The first lead 5A is a wiring member formed by bending a metal plate such as a copper plate and is bonded to the first main terminal 801 and the first conductor pattern 201 by using a bonding material (not illustrated) such as solder. The emitter electrodes 301 provided on the upper surfaces of the semiconductor elements 3A and 3B are electrically connected to a first conductor block 212 disposed on the upper surface of the second conductor pattern 202 via the first wiring member 6A to be described later. The first conductor block 212 is bonded to the second conductor pattern 202 by using a bonding material (not illustrated) such as solder. The second conductor pattern 202 is electrically connected to the third main terminal 803 via the second lead 5B. The second lead 5B is a wiring member formed by bending a metal plate such as a copper plate and is bonded to the second conductor pattern 202 and the third main terminal 803 by using a bonding material (not illustrated) such as solder. The gate electrodes 302 provided on the upper surfaces of the semiconductor elements 3A and 3B are electrically connected to the inner terminal portion of the control terminal 804 by the bonding wires 7A and 7B.

Each of the semiconductor elements 3C and 3D disposed on the second conductor pattern 202 of the wiring board 2 includes a collector electrode (not illustrated) on the lower surface, and the collector electrode is bonded to the second conductor pattern 202 by using a bonding material (not illustrated) such as solder. The emitter electrodes 301 provided on the upper surfaces of the semiconductor elements 3C and 3D are electrically connected to a second conductor block 213 disposed on the upper surface of the third conductor pattern 203 of the wiring board 2 via the second wiring member 6B to be described later. The second conductor block 213 is bonded to the third conductor pattern 203 by using a bonding material (not illustrated) such as solder. The third conductor pattern 203 is electrically connected to the second main terminal 802 via the third lead 5C. The third lead 5C is a wiring member formed by bending a metal plate such as a copper plate and is bonded to the third conductor pattern 203 and the second main terminal 802 by using a bonding material (not illustrated) such as solder. The gate electrodes 302 provided on the upper surfaces of the semiconductor elements 3C and 3D are electrically connected to the inner terminal portion of the control terminal 805 by the bonding wires 7C and 7D.

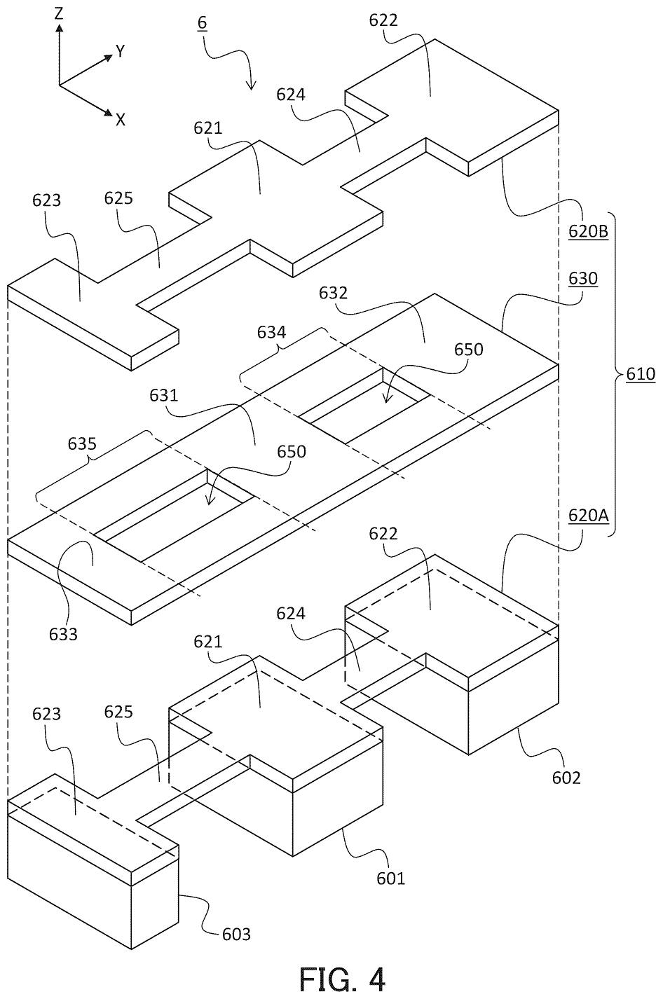

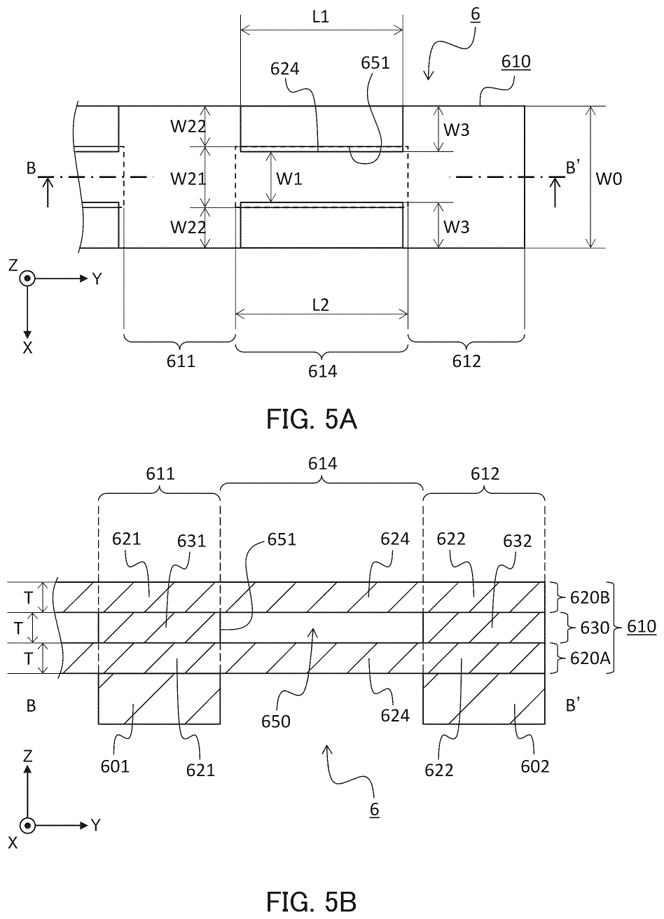

FIG. 4 is an exploded perspective view for explaining a first configuration example of a wiring member. FIG. 5A is a plan view of the wiring member illustrated in FIG. 4, and FIG. 5B is a cross-sectional view taken along line B-B′ in FIG. 5A. The wiring member 6 illustrated in FIGS. 4, 5A, and 5B may be the first wiring member 6A and the second wiring member 6B described above.

The illustrated wiring member 6 includes three conductor spacers 601 to 603 and a laminate 610 that connects the conductor spacers 601 to 603. The conductor spacers 601 to 603 are each, for example, a plate-shaped or block-shaped metal member such as a copper plate or a copper block. The laminate 610 is obtained by disposing conductor foils such as copper foils in a laminated manner. FIGS. 4 and 5B illustrate the three-layer laminate 610 in which a second-shaped conductor foil 630 is disposed between two first-shaped conductor foils 620A and 620B, but the number and type of conductor foils to be laminated are not limited thereto.

The first conductor spacer 601 and the second conductor spacer 602 are disposed on the emitter electrode 301 of the semiconductor element 3, and are bonded to the emitter electrode 301 by using a bonding material (not illustrated) such as solder. In the case of the second wiring member 6B, as illustrated in FIG. 2, the first conductor spacer 601 is bonded to the emitter electrode of the semiconductor element 3C, and the second conductor spacer 602 is bonded to the emitter electrode of the semiconductor element 3D. The third conductor spacer 603 is disposed in a direction opposite to the second conductor spacer 602 as viewed from the first conductor spacer 601, and is connected to a conductor different from the emitter electrode of the semiconductor element 3. In the case of the second wiring member 6B, the third conductor spacer 603 is bonded to the second conductor block 213 disposed on the third conductor pattern 203 of the wiring board 2 by using, for example, a bonding material (not illustrated) such as solder. As will be described later, the second conductor block 213 and the first conductor block 212 may be omitted.

In the laminate 610, the first-shaped conductor foil 620A, the second-shaped conductor foil 630, and the first-shaped conductor foil 620B are disposed in a laminated manner in this order. The three conductor foils 620A, 630, and 620B are disposed in a laminated manner at different distances from the emitter electrode 301 when the first conductor spacer 601 and the second conductor spacer 602 are bonded to the emitter electrode 301 of the semiconductor element 3. In other words, the three conductor foils 620A, 630, and 620B are disposed in a laminated manner on a surface (upper surface) of the first conductor spacer 601 opposite to a surface (lower surface) facing the emitter electrode 301 of the semiconductor element 3 at different distances from the upper surface of the first conductor spacer 601. The conductor foils 620A, 630, and 620B are each formed, for example, by punching using a conductor foil such as a copper foil having a thickness T of about 100 μm as a material. It is sufficient that the laminate 610 be obtained by disposing at least three conductor foils in a laminated manner. The thickness T of the conductor foil is not limited to a specific thickness. Conductor foils having different thicknesses may be disposed in a laminated manner. For example, the thickness of the second-shaped conductor foil 630 disposed between the two first-shaped conductor foils 620A and 620B may be greater than the thicknesses of the first-shaped conductor foils 620A and 620B. The number of conductor foils to be disposed in a laminated manner may be changed depending on the total thickness of the laminate 610 satisfying the requirements of electrical characteristics in the semiconductor module 1 and the thickness T of each conductor foil.

Each of the conductor foils 620A, 630, and 620B of the laminate 610 includes a first connection region, a second connection region, and a third connection region, a first linking region, and a second linking region. First connection regions 621, 631, and 621 of the conductor foils 620A, 630, and 620B are connection regions with the first conductor spacer 601, and have a planar shape overlapping the upper surface of the first conductor spacer 601 in plan view of the upper surface of the first conductor spacer 601 (XY plane). Second connection regions 622, 632, and 622 of the conductor foils 620A, 630, and 620B are connection regions with the second conductor spacer 602, and have a planar shape overlapping the upper surface of the second conductor spacer 602 in plan view of the upper surface of the second conductor spacer 602 (XY plane). Third connection regions 623, 633, and 623 of the conductor foils 620A, 630, and 620B are connection regions with the third conductor spacer 603, and have a planar shape overlapping the upper surface of the third conductor spacer 603 in plan view of the upper surface of the third conductor spacer 603 (XY plane). In the laminate 610 illustrated in FIG. 5A, the first connection regions 621, 631, and 621 of the respective conductor foils 620A, 630, and 620B overlap each other in a first connection region 611, and the second connection regions 622, 632, and 622 of the respective conductor foils 620A, 630, and 620B overlap each other in a second connection region 612.

First linking region 624, 634, or 624 of the conductor foil 620A, 630, or 620B is a region that links the corresponding first connection region 621, 631, or 621 and the corresponding second connection region 622, 632, or 622. Second linking region 625, 635, or 625 of the conductor foil 620A, 630, or 620B is a region that links the corresponding first connection region 621, 631, or 621 and the corresponding third connection region 623, 633, or 623. In the second-shaped conductor foil 630 disposed between the first-shaped conductor foils 620A and 620B, the first linking region (void formation area) 634 and the second linking region (void formation area) 635 each include an opening 650 that forms a void in each linking region in the laminate 610. The opening 650 is a space region surrounded by wall surfaces 651 each connecting an opening end of the upper surface and an opening end of the lower surface of the conductor foil 630. Each of the first linking region 624 and the second linking region 625 of the first-shaped conductor foils 620A and 620B illustrated in FIGS. 4, 5A, and 5B has a planar shape that passes through an opening region (opening 650) in the linking region of the second conductor foil 630 in plan view and does not overlap the second conductor foil 630. That is, in a first linking region 614 in the laminate 610 illustrated in FIG. 5A, the first linking regions of the conductor foils 620A, 630, and 620B are laminated so that the linking regions of the adjacent conductor foils in the laminating direction are not in contact with each other. Note that the two conductor foils disposed with the second-shaped conductor foil 630 interposed therebetween are not limited to the combination of conductor foils having the same shape as illustrated in FIG. 4, and may be a combination of conductor foils having different shapes.

In the laminate 610 illustrated in FIG. 5A, the second-shaped conductor foil 630 has a strip-shaped outer shape having a width (dimension in the X direction) W0 in plan view, and the opening 650 having a width W21 (<W0) is provided in the first linking region 634 and the second linking region 635 such that a distance from an end of the second conductor foil 630 in the width direction is W22. The first linking regions 624 in the first-shaped conductor foils 620A and 620B are formed in a band shape having a width smaller than those of the first connection regions 621 and the second connection regions 622 such that a width W1 satisfies W21>W1 and a distance W3 from the end of each conductor foil 620 in the width direction satisfies W3>W22 in plan view.

Note that, in the first configuration example of the wiring member 6, the relationship between the width (dimension in the X direction) W21 of the opening 650 formed in the first linking region 634 of the second-shaped conductor foil 630 and the width W1 of the first linking regions 624 of the first-shaped conductor foils 620A and 620B is not limited to the relationship of W21>W1 as illustrated in FIG. 5A. The relationship between the width W21 and the width W1 may be W21=W1, or may be W21<W1 as long as the deformation of the laminate 610 described later is not hindered. Furthermore, in the first configuration example of the wiring member 6, the relationship between a length (dimension in the Y direction) L2 of the opening 650 formed in the first linking region 634 of the second-shaped conductor foil 630 and a length L1 of the first linking regions 624 of the first-shaped conductor foils 620A and 620B is not limited to the relationship of L2>L1 as illustrated in FIG. 5A. The relationship between the length L2 and the length L1 may be L2≤L1.

In the conductor foils 620A, 630, and 620B disposed in a laminated manner, the connection regions overlapping each other are bonded to the upper surfaces of the conductor spacers 601 to 603 by, for example, using a bonding material (not illustrated) such as solder or laser welding. That is, in the laminate 610 of the wiring member 6, the connection regions of the conductor foils disposed in a laminated manner are bonded to each other in the connection region overlapping the conductor spacer in plan view (for example, the connection regions 611 and 612 in FIG. 5A), and a change in the relative position between the conductor foils is restricted. On the other hand, a change in the relative position between the conductor foils disposed in a laminated manner is allowed in the linking region (for example, the linking region 614 in FIG. 5A). In other words, the laminate 610 allows the plurality of conductor foils disposed in a laminated manner in the linking region to be deformed separately.

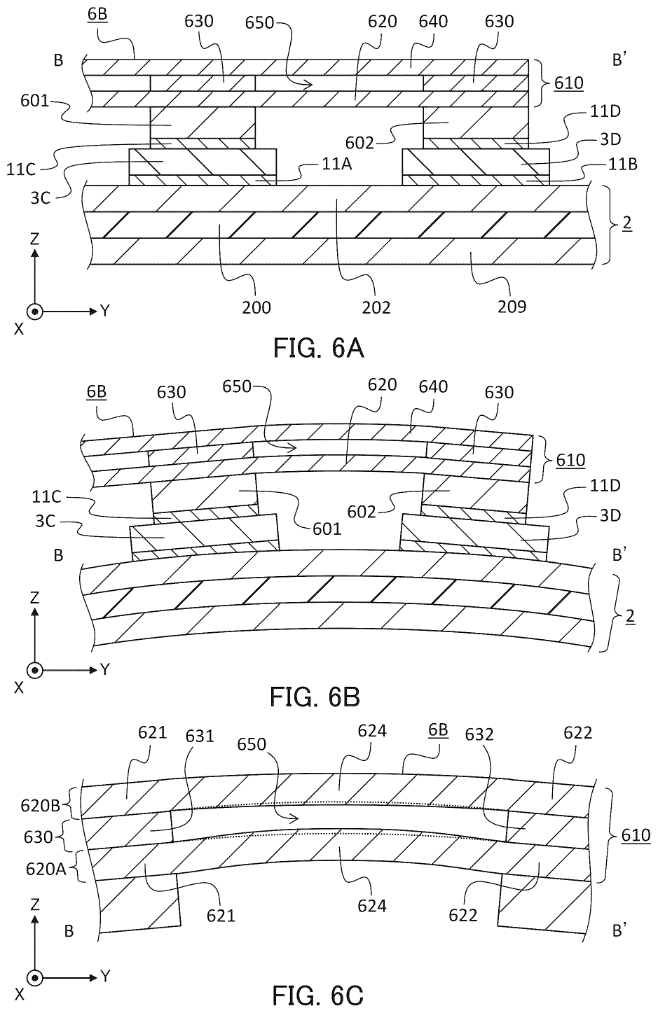

FIG. 6A is a cross-sectional view for explaining a connecting process of connecting emitter electrodes of semiconductor elements with a wiring member. FIG. 6B is a cross-sectional view for explaining an example of warpage generated in a wiring board. FIG. 6C is a cross-sectional view for explaining an example of warpage of the wiring member. The cross-sectional views of FIGS. 6A to 6C may be enlarged, fragmentary cross-sectional views obtained by enlarging a portion corresponding to the cross-sectional view taken along line B-B′ in FIG. 5A in the cross-sectional view of the semiconductor module 1 in FIG. 2.

The manufacturing process of the semiconductor module 1 described above includes a bonding process of bonding the conductors to each other by using a bonding material such as solder. In the bonding process, for example, bonding of the conductor pattern of the wiring board 2 and the collector electrode of the semiconductor element 3, bonding of the emitter electrode 301 of the semiconductor element 3 and the wiring member 6, and the like are collectively performed. In the bonding process, as illustrated in FIG. 6A, bonding materials (solders) 11A and 11B and the semiconductor elements 3C and 3D are disposed in this order on the second conductor pattern 202 of the wiring board 2. Bonding materials (solders) 11C and 11D and the wiring member 6B are then disposed in this order on the emitter electrodes (not illustrated) of the semiconductor elements 3C and 3D. Thereafter, the bonding materials 11A to 11D are heated and melted. In the bonding process, a bonding material (solder), the semiconductor element, a bonding material (solder), and the wiring member 6A are also disposed in this order on the first conductor pattern 201 of the wiring board 2 and bonded in the same manner.

When the bonding materials 11A to 11D are heated, the surrounding wiring board 2, wiring member 6B, and the like are also heated and expanded. The linear expansion coefficient of the ceramic material used as the insulating substrate 200 of the wiring board 2 is, for example, about 3 to 7 ppm/° C., and the linear expansion coefficient of copper used for the conductor patterns 201 to 203 is about 17 ppm/° C. Therefore, when the bonding materials 11A to 11D are heated, for example, the wiring board 2 may be warped as illustrated in FIG. 6B.

In the plurality of conductor foils 620A, 630, and 620B disposed in a laminated manner in the wiring member 6B described above, the conductor foils are not bonded to each other between the connection regions overlapping the upper surfaces of the conductor spacers 601 to 603 disposed on the emitter electrode of the semiconductor element 3, and the linking region that allows each conductor foil to be deformed separately is provided. In the linking regions of the laminate 610, a void is formed by the opening 650 of the second-shaped conductor foil 630 between the two first-shaped conductor foils 620A and 620B. Therefore, when warpage is generated in the wiring board 2, as illustrated in FIG. 6C, the wiring member 6B is deformed such that the first linking region 624 of the conductor foil 620A and the first linking region 624 of the conductor foil 620B enter the opening 650 of the conductor foil 630, and follows the warpage of the wiring board 2.

That is, as compared with the case of using a lead formed of a single copper plate having the same thickness as the laminate 610 as described in JP 2018-61066 A, W0 2018/142863 A, and US 2008-0,246,130 A, the wiring member 6 of the first configuration example described above has high pliability (flexibility) and is flexibly deformed in accordance with the magnitude of the warpage generated in the wiring board 2. In addition, in the two adjacent conductor foils in the wiring member 6 of the first configuration example described above, the linking region of one conductor foil includes therein a region not in contact with a portion in the linking region of the other conductor foil. Therefore, as also compared with the case of using a laminate in which the whole in the linking region of each conductor foil is in contact with the inside of the linking region of adjacent conductor foils as described in, for example, JP 2003-188328 A, WO 2020/255663 A, JP H09-115965 A, and JP H07-288269 A, the wiring board 6 of the first configuration example has high pliability (flexibility) and is flexibly deformed in accordance with the magnitude of the warpage generated in the wiring board 2. When a lead formed of a single copper plate or a laminate in which the whole in the linking region of each conductor foil is in contact with the inside of the linking region of the adjacent conductor foils is used, the wiring member 6 cannot follow the warpage of the wiring board 2. For example, the bonding materials on the emitter electrodes of the plurality of semiconductor elements 3 connected by the wiring member 6 and the bonding materials connecting the wiring board and the collector electrodes of the semiconductor elements 3 may vary in shape (i.e., the shapes of bonding materials may be non-uniform).

On the other hand, in the wiring member 6 of the first configuration example, also in the case in which the wiring board 2 is warped in the bonding process, variations in shape (i.e., non-uniformity of the shape) can be reduced between the bonding materials 11C and 11D that bond the conductor spacers 601 and 602 of the wiring member 6 to the emitter electrodes of the semiconductor elements 3C and 3D. Variations in electrical characteristics of the semiconductor modules 1 due to variations in the shape of the bonding material can be reduced. Stress concentration of the bonding material during use of the semiconductor module 1 due to variations can also be reduced, and reliability is improved.

For example, in the semiconductor module 1, warpage is generated in the wiring board 2 due to heat generated by the semiconductor element 3 during operation. Also in this case, the linking region of the wiring member 6 is deformed in accordance with the warpage of the wiring board 2. In this way, for example, stress applied to the bonding portion between the conductor spacers 601 and 602 and the emitter electrodes of the semiconductor elements 3C and 3D can be reduced, and reliability is improved.

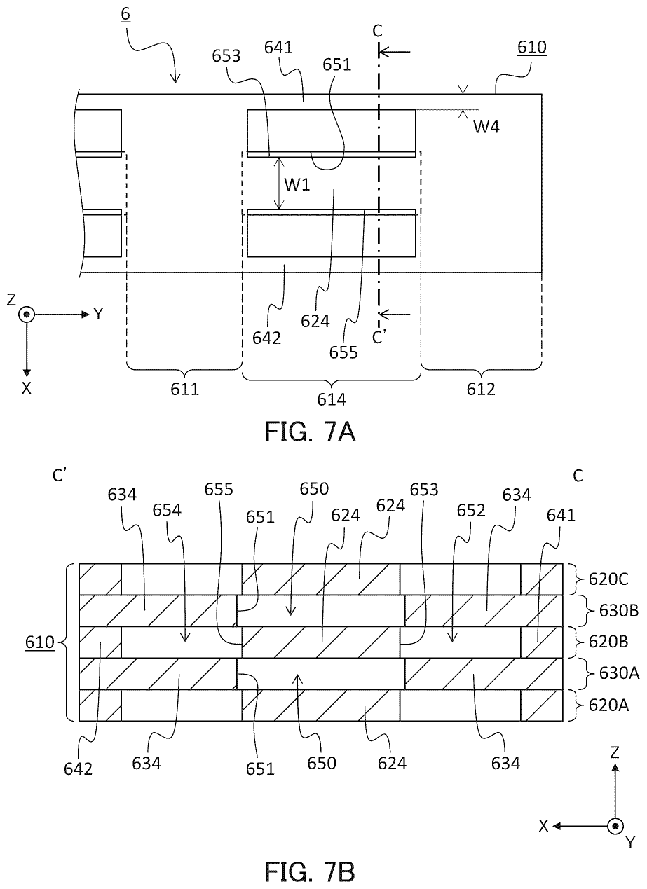

FIG. 7A is a plan view for explaining a second configuration example of the wiring member, and FIG. 7B is a cross-sectional view taken along line C-C′ in FIG. 7A. Note that FIG. 7B illustrates only a cross-sectional configuration of a part of the laminate 610 of the wiring member 6. The wiring member 6 illustrated in FIGS. 7A and 7B may be the wiring members 6A and 6B illustrated in FIGS. 1 and 2.

The laminate 610 of the wiring member 6 illustrated in FIGS. 7A and 7B has a five-layer structure in which three first-shaped conductor foils 620A to 620C and two second-shaped conductor foils 630A and 630B are alternately laminated. The openings 650 are formed in the linking regions 634 and 635 of the second-shaped conductor foils 630A and 630B (see FIG. 4).

On the other hand, the first-shaped conductor foil 620 in the wiring member 6 of the second configuration example includes: the first linking region (first linking portion) 624 that passes through the opening region (opening 650) of the second-shaped conductor foil 630 in plan view; and a second linking portion 641 and a third linking portion 642 that overlap the respective end portions of the conductor foil 630 in the width direction (X direction) in plan view and link the first connection region 621 and the second connection region 622. A width W4 of the second linking portion 641 and the third linking portion 642 is not limited to a specific width and may be smaller than the width W1 of the first linking region (first linking portion) 624 in order to reduce an area overlapping the second-shaped conductor foil 630. That is, in the first-shaped conductor foil 620 in the wiring member 6 of the second configuration example, an opening 652 surrounded by wall surfaces 653 and an opening 654 surrounded by wall surfaces 655 are formed in the linking region.

In the wiring member 6 as described above, the second linking portion 641 and the third linking portion 642 of the conductor foil 620B disposed between the two second-shaped conductor foils 630A and 630B serve as walls, and voids are formed between the conductor foils 630A and 630B by the openings 652 and 654. Therefore, for example, the sealing material (insulating resin) can be restrained from entering the void (opening 652 and 654) formed between the second-shaped conductor foils 630A and 630B in the sealing process performed after the bonding process. In the wiring member 6 of the second configuration example, the width W21 (see FIG. 5A) of the opening 650 of the second-shaped conductor foil 630 and the width W1 of the first linking region 624 of the first-shaped conductor foils 620A and 620B are set to W21˜W1. With this configuration, the scaling material (insulating resin) can be restrained from entering the opening 650 of the conductor foil 630 through the gap between the opening 650 of the conductor foil 630 and the first linking region 624 of the conductor foil 620. A void formed by the opening 650 of the second-shaped conductor foil 630 and voids formed by the openings 652 and 654 of the first-shaped conductor foil 620 remain after the scaling process, so that an effect of allowing the linking region of each conductor foil to be deformed separately is maintained. That is, the wiring member 6 of the second configuration example can reduce lowering of the pliability (flexibility) of the wiring member 6 due to filling of the scaling material (insulating resin) into the void.

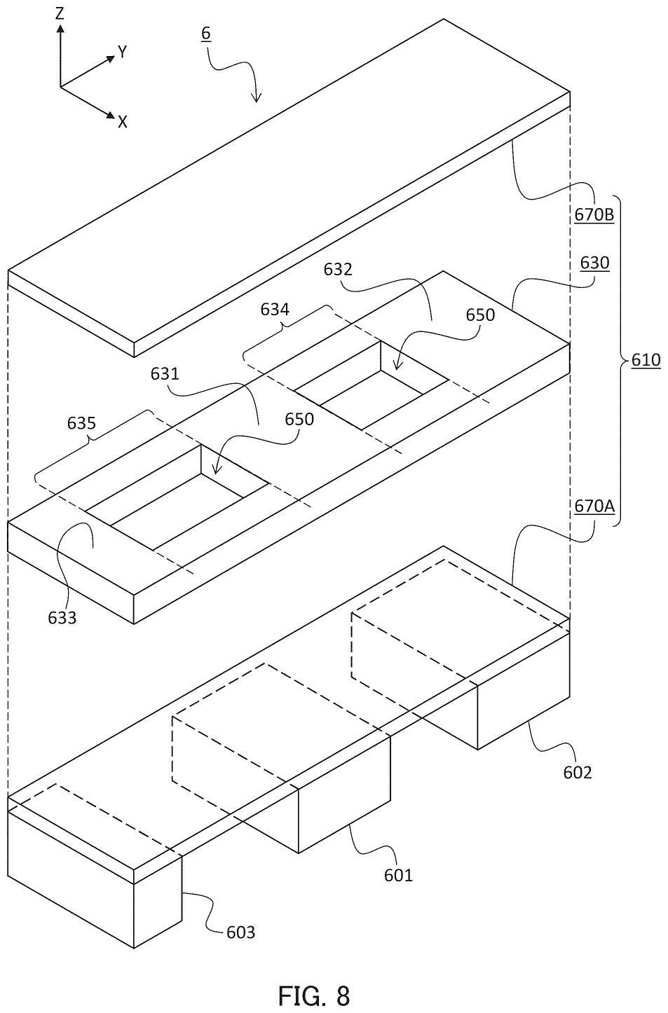

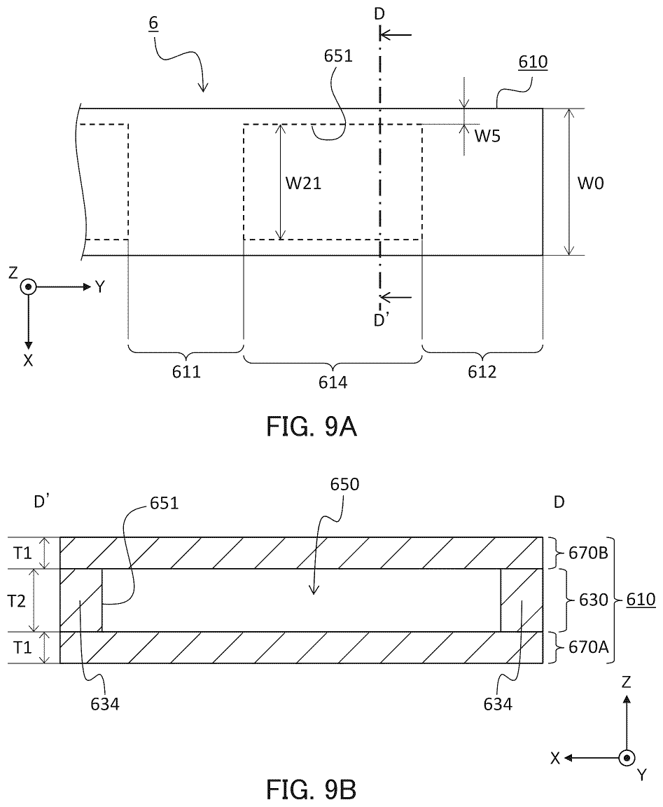

FIG. 8 is an exploded perspective view for explaining a third configuration example of the wiring member. FIG. 9A is a plan view of the wiring member illustrated in FIG. 8, and FIG. 9B is a cross-sectional view taken along line D-D′ in FIG. 9A. The wiring member 6 illustrated in FIGS. 8, 9A, and 9B may be the wiring members 6A and 6B illustrated in FIGS. 1 and 2.

The wiring member 6 illustrated in FIG. 8 includes the laminate 610 having a three-layer structure in which the second-shaped conductor foil 630 including the opening region (opening 650) in a linking region is disposed between a pair of flat plate-shaped conductor foils 670A and 670B. In other words, it can be said that the linking region of the laminate 610 in the wiring member 6 of the third configuration example has a tubular shape including a hollow portion whose axial direction is a direction from the connection end connected to one conductor spacer (for example, the first conductor spacer 601) toward the connection end connected to the other conductor spacer (for example, the second conductor spacer 602). In this example, as illustrated in FIGS. 9A and 9B, the opening 650 of the second-shaped conductor foil 630 may have an increased dimension W21 in the width direction (X direction) and a reduced contact area with the conductor foils 670A and 670B in the linking region. Note that, in the wiring member 6 of the third configuration example, the dimension W21 in the width direction of the opening 650 in the linking region of the second-shaped conductor foil 630 and a width W5 of the linking portion (not illustrated) at the end portion in the width direction are not limited to a specific relationship. In the semiconductor module 1 that is used as a power conversion apparatus as exemplified in the present specification and operates at a high frequency, a current flowing through the laminate 610 in which the second-shaped conductor foil 630 is disposed between the pair of flat plate-shaped conductor foils 670A and 670B is concentrated on the surface of the laminate 610 (in particular, the upper surface of the conductor foil 670A and the lower surface of the conductor foil 670B) due to the skin effect. For this reason, it is sufficient that the width W5 of the linking portion in the linking region of the conductor foil 630 be, for example, a size with which the shape of the conductor foil 630 can be maintained. In this case, it is sufficient that a thickness T2 of the conductor foil 630 illustrated in FIG. 9B be enough to restrain the linking regions of the upper and lower conductor foils 670A and 670B from coming into contact with each other in the opening 650 of the conductor foil 630. That is, the relationship between the thickness T2 of the conductor foil 630 and the thickness T1 of the conductor foils 670A and 670B may be T2=T1.

The laminate 610 in the wiring member 6 of the third configuration example may be formed by disposing, in a laminated manner, a plurality of conductor foils having the same planar shape as the second-shaped conductor foil 630 between the upper and lower conductor foils 670A and 670B.

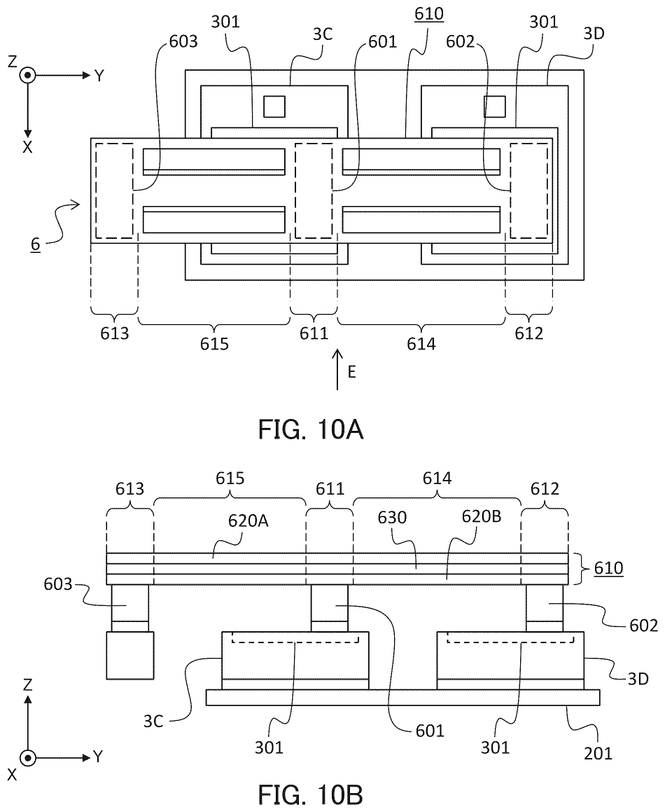

FIG. 10A is a plan view for explaining a fourth configuration example of the wiring member, and FIG. 10B is a view of the wiring member as viewed in the direction of arrow E in FIG. 10A. The wiring member 6 illustrated in FIGS. 10A and 10B may be the wiring members 6A and 6B illustrated in FIGS. 1 and 2.

The shape of the conductor spacers 601 to 603 in the wiring member 6 according to the present embodiment can be suitably changed. The shapes of the conductor spacers 601 and 602 in the wiring member 6 of the fourth configuration example illustrated in FIGS. 10A and 10B represents an example of a rectangular parallelepiped in which the area of the lower surfaces of the semiconductor elements 3C and 3D bonded to the emitter electrodes 301 is smaller than the area of the upper surfaces of the emitter electrodes 301. Specifically, a diagram of a rectangular parallelepiped in which the former area is half or less of the latter area is illustrated. In the wiring member 6 of the fourth configuration example illustrated in FIGS. 10A and 10B, the areas of the first connection region 611 and the second connection region 612 can be reduced by an amount corresponding to the reduced areas of the lower surface and the upper surface of the conductor spacers 601 and 602, and accordingly, the linking region 614 between the connection regions can be lengthened. The wiring member 6 of the fourth configuration example may include a region where the void formed in the linking region 614 in the laminate 610 overlaps the emitter electrode 301 of the semiconductor element 3 in plan view. That is, in the wiring member 6 of the fourth configuration example, the opening 650 can be expanded so that a part of the opening 650 of the second-shaped conductor foil 630 overlaps the emitter electrode 301 of the semiconductor element 3 in plan view, and the pliability (flexibility) can be further increased. Note that the relationship between the planar shapes of the conductor spacers 601 and 602 and the planar shape of the emitter electrode 301, the position of the conductor spacer on the emitter electrode 301, and the like are not limited to a specific relationship and position.

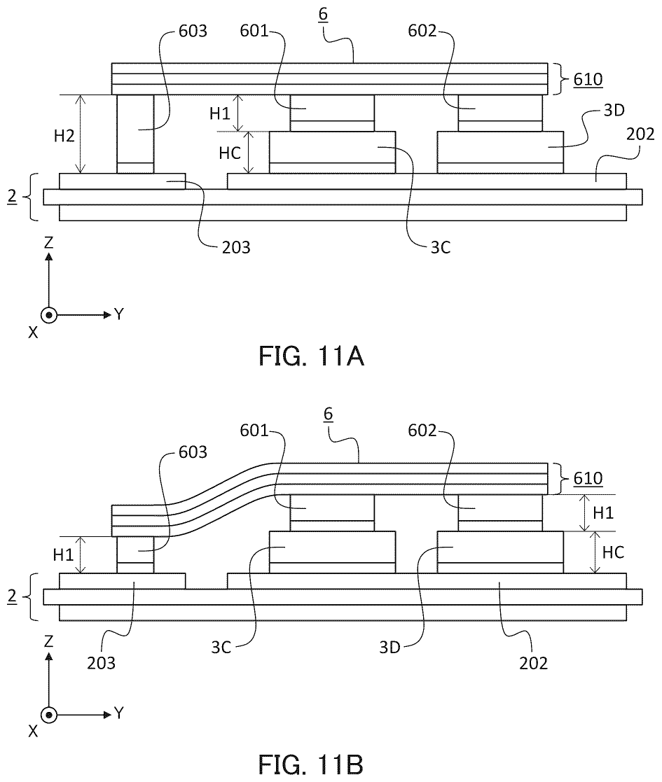

FIG. 11A is a front view for explaining a fifth configuration example of the wiring member, and FIG. 11B is a front view for explaining a sixth configuration example of the wiring member. The front views in FIGS. 11A and 11B correspond to the view as viewed in the direction of arrow E in FIG. 10A. The wiring member 6 illustrated in FIGS. 11A and 11B may be the wiring members 6A and 6B illustrated in FIGS. 1 and 2.

In the semiconductor module 1 illustrated in FIGS. 1 and 2, the third conductor spacer 603 of the wiring member 6 and the conductor block disposed on the conductor pattern of the wiring board 2 are bonded by using a bonding material. However, in the semiconductor module 1 according to the present embodiment, for example, as illustrated in FIG. 11A, a height H2 of the third conductor spacer 603 of the wiring member 6 may be made greater than a height H1 of the first conductor spacer 601 and the second conductor spacer 602, and the third conductor spacer 603 and the conductor pattern 203 of the wiring board 2 may be directly bonded to each other by using a bonding material. Note that the relationship between a height (thickness) HC of the semiconductor elements 3C and 3D to which the first conductor spacer 601 and the second conductor spacer 602 are connected and the height H1 of the first conductor spacer 601 and the second conductor spacer 602 is not limited to a specific relationship. The relationship may be H1>HC, opposite to the relationship illustrated in FIGS. 11A and 11B.

For another example, in the wiring member 6 as illustrated in FIG. 11B, the conductor spacers 601 to 603 may be set to have the height H1, a linking region between the connection region with the first conductor spacer 601 and the connection region with the third conductor spacer 603 in the laminate 610 may be bent, and the third conductor spacer 603 and the conductor pattern 203 of the wiring board 2 may be directly bonded by using a bonding material.

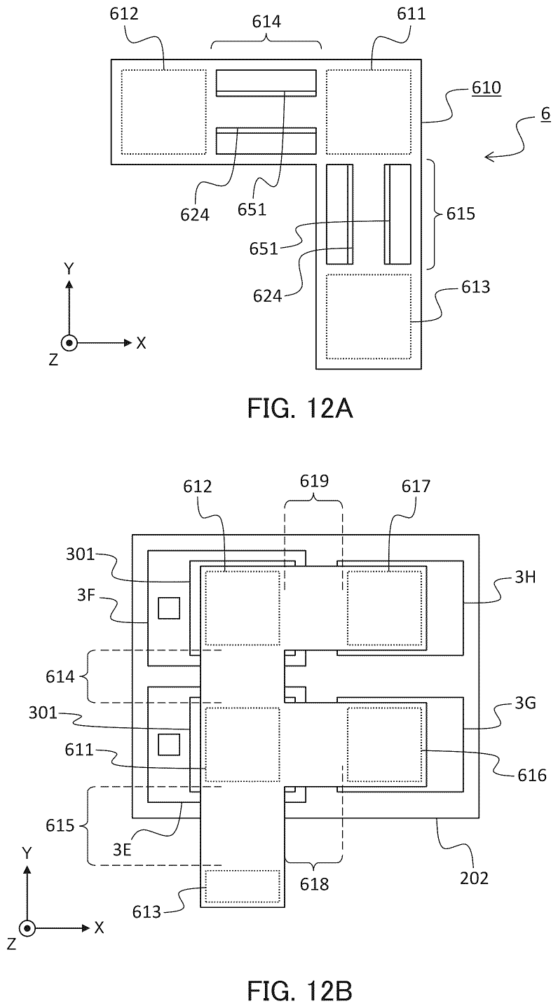

FIG. 12A is a front view for explaining a seventh configuration example of the wiring member, and FIG. 12B is a plan view for explaining an eighth configuration example of the wiring member. The wiring member 6 illustrated in FIGS. 12A and 12B may be the wiring members 6A and 6B illustrated in FIGS. 1 and 2.

FIG. 12A illustrates the wiring member 6 in which the planar shape of the laminate 610 is an L shape. In each conductor foil of the laminate 610 in the wiring member 6 of the seventh configuration example illustrated in FIG. 12A, the second connection region 612 is located on the negative side in the X direction, and a third connection region 613 is located on the negative side in the Y direction, as viewed from the first connection region 611. In the first linking region 614 that links the first connection region 611 and the second connection region 612, the linking region 624 of the first-shaped conductor foils 620A and 620B passing through the opening (region surrounded by the wall surfaces 651) of the linking region of the second-shaped conductor foil 630 extends in the direction from the first connection region toward the second connection region (X direction). In a second linking region 615 that links the first connection region 611 and the third connection region 613, the linking region 624 of the first-shaped conductor foils 620A and 620B passing through the opening (region surrounded by the wall surfaces 651) of the linking region of the second-shaped conductor foil 630 extends in the direction from the first connection region toward the third connection region (Y direction).

That is, the planar shape of the wiring member 6 according to the present embodiment can be suitably changed in accordance with the layout of a plurality of conductors connected by one wiring member 6. For example, the wiring member 6 of the seventh configuration example in FIG. 12A can be applied to connect the emitter electrodes of the semiconductor element 3 disposed at the position corresponding to the second connection region 612 and the position corresponding to the third connection region 613 on the upper surface of the wiring board 2 when the X direction and the Y direction are the extending directions of the end side of the wiring board 2 of the semiconductor module 1.

The laminate 610 of the wiring member 6 may include four or more connection regions. For example, in FIG. 12B, four semiconductor elements 3E, 3F, 3G, and 3H are disposed on the second conductor pattern 202 of the wiring board 2. The semiconductor elements 3E and 3F may function as switching elements such as IGBT elements, and the semiconductor elements 3G and 3H may function as diode elements such as FWD elements. The laminate 610 in the wiring member 6 of the eighth configuration example illustrated in FIG. 12B includes the first connection region 611 overlapping the emitter electrode 301 of the semiconductor element 3E, the second connection region 612 overlapping the emitter electrode 301 of the semiconductor element 3F, and the third connection region 613 overlapping a conductor pattern different from the second conductor pattern 202 (not illustrated). The laminate 610 in the wiring member 6 of the eighth configuration example further includes a fourth connection region 616 overlapping the anode electrode of the semiconductor element 3G, a fifth connection region 617 overlapping the anode electrode of the semiconductor element 3H, a third linking region 618 linking the first connection region 611 and the fourth connection region 616, and a fourth linking region 619 linking the second connection region 612 and the fifth connection region 617. Although not illustrated in FIG. 12B, the above-described void is formed in each of the linking regions 614, 615, 618, and 619 of the laminate 610.

As described above, the wiring member 6 according to the present embodiment can freely change the planar shape of the laminate 610 in accordance with the number and arrangement of conductors connected by the wiring member 6. The wiring member 6 described above is not limited to a member that connects the emitter electrode 301 of the semiconductor element 3 and the conductor (for example, a conductor pattern, a conductor block on the conductor pattern, or the like) on the wiring board 2, and may be used as, for example, a member that connects the conductor pattern of the wiring board 2 and the main terminal of the case 8. The planar shape of the intermediate conductor foil disposed between the two conductor foils in the laminate 610 is not limited to the shape including the rectangular opening 650 like the second-shaped conductor foil 630 described above with reference to FIG. 4 and the like.

The switching element of the semiconductor module 1 as described above with reference to FIGS. 1 to 3 is not limited to an IGBT element, and may include, for example, a power metal oxide semiconductor field effect transistor (MOSFET), or a bipolar junction transistor (BJT). When the switching element is a power MOSFET, the electrode on the lower surface of the semiconductor element 3 may be referred to as a drain electrode, and the electrode on the upper surface may be referred to as a source electrode. Also, the diode element connected in anti-parallel with the switching element may include, for example, a schottky barrier diode (SBD), a junction barrier schottky (JBS) diode, a merged PN schottky (MPS) diode, or a PN diode.

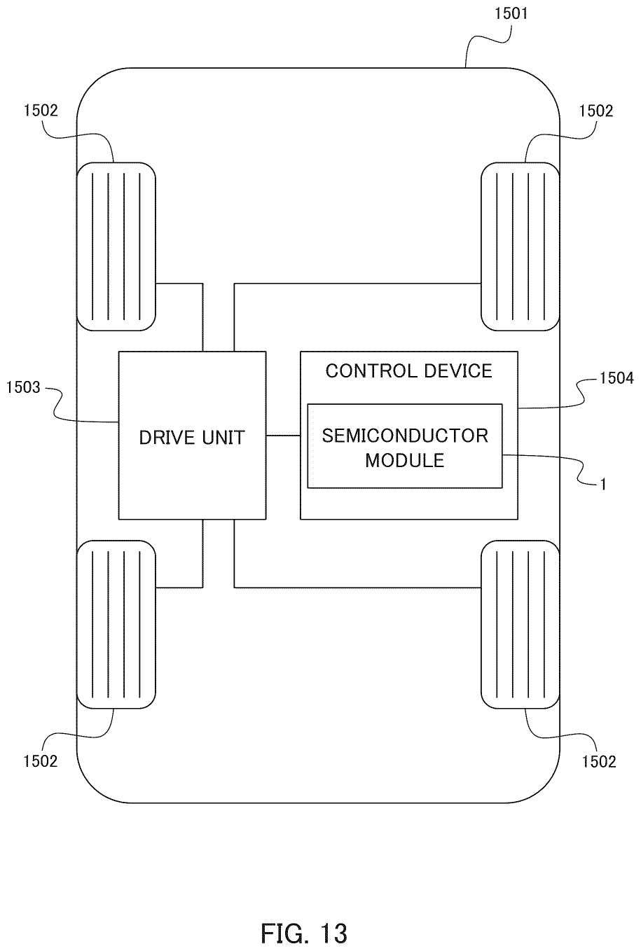

The semiconductor module 1 of the above-described embodiment is not limited to that for a specific application, but in particular, the semiconductor module 1 including the cooler 10 is suitable for use in a high-temperature environment. For example, the semiconductor module 1 of the above-described embodiment may be applied to a power conversion apparatus such as an inverter apparatus of an in-vehicle motor. A vehicle to which the semiconductor module 1 according to the present invention is applied is described with reference to FIG. 13.

FIG. 13 is a schematic plan view for illustrating an example of a vehicle to which the semiconductor module according to the embodiment is applied. A vehicle 1501 illustrated in FIG. 13 is configured with, for example, a four-wheeled vehicle including four wheels 1502. The vehicle 1501 may be, for example, an electric vehicle that drives wheels by a motor or the like, or a hybrid vehicle using power of an internal combustion engine in addition to the motor. Also, the vehicle to which the semiconductor module 1 is applied is not limited to a four-wheeled vehicle, and may be a two-wheeled vehicle, a railway vehicle, or the like.

The vehicle 1501 includes a drive unit 1503 that applies power to the wheels 1502 and a control device 1504 that controls the drive unit 1503. The drive unit 1503 may include, for example, at least one of an engine, the motor, and a hybrid of the engine and the motor.

The control device 1504 performs control (for example, power control) on the drive unit 1503. The control device 1504 includes the semiconductor module 1 including the cooler 10 of the above-described embodiment. The semiconductor module 1 may be configured to perform power control on the drive unit 1503.

The semiconductor module 1 of the above-described embodiment may be applied to, for example, an industrial power conversion apparatus such as an inverter apparatus that drives a motor of an elevator, an escalator, or an air conditioning system of a building. Also, the circuit formed in the semiconductor module 1 is not limited to the half-bridge inverter circuit as illustrated in FIG. 3. The circuit formed in the semiconductor module 1 may include, for example, only an upper arm (circuit portion between the first main terminal 801 and the third main terminal 803) or a lower arm (circuit portion between the third main terminal 803 and the second main terminal 802) in the half-bridge circuit in FIG. 3, or may include a plurality of (for example, three) half-bridge inverter circuits. The circuit formed in the semiconductor module 1 may be a full-bridge inverter circuit. Furthermore, the circuit formed in the semiconductor module 1 is not limited to the power conversion circuit that converts direct current into alternating current, and may be another circuit or may include the power conversion circuit and another circuit.

Hereinafter, feature points in the above-described embodiments will be summarized.

A semiconductor module according to the above-described embodiment includes a wiring board including an insulating substrate, and a conductor pattern being disposed on a first surface of the insulating substrate; a semiconductor element being disposed on the conductor pattern of the wiring board, the semiconductor element being connected to the conductor pattern; and a wiring member being configured to electrically connect another conductor and an electrode that is provided on a surface of the semiconductor element, the surface being opposite the conductor pattern, the wiring member includes a first conductor spacer being bonded to the electrode of the semiconductor element, a second conductor spacer being bonded to the other conductor, and a laminate including a plurality of conductor foils being configured to connect the first conductor spacer and the second conductor spacer, the plurality of conductor foils being disposed in a laminated manner at different distances from the surface of the semiconductor element on which the electrode is formed, each of the plurality of conductor foils of the laminate includes a first connection region serving as a connection region with the first conductor spacer, a second connection region serving as a connection region with the second conductor spacer, and a linking region between the first connection region and the second connection region, the plurality of conductor foils includes at least one intermediate conductor foil, and a first conductor foil and a second conductor foil being disposed in a laminated manner with the at least one intermediate conductor foil being interposed between the first conductor foil and the second conductor foil, and each of the at least one intermediate conductor foil includes a void formation portion that forms a void between the linking region of the first conductor foil and the linking region of the second conductor foil.

In the semiconductor module according to the above-described embodiment, the laminate has a tubular shape including the void being formed by the void formation portion of each of the at least one intermediate conductor foil, the void extending at least from a boundary between the first connection region and the linking region to a boundary between the second connection region and the linking region.

In the semiconductor module according to the above-described embodiment, in plan view of the surface of the semiconductor element on which the electrode is formed, each of the plurality of conductor foils of the laminate has a planar shape that does not overlap each other at least between each adjacent conductor foils among the plurality of conductor foils in a region in the linking region excluding an end portion of the linking region.

In the semiconductor module according to the above-described embodiment, the void formation portion of each of the at least one intermediate conductor foil is an opening including, in the linking region, an opening region in which a surface facing the first conductor foil and a surface facing the second conductor foil are open, and the first conductor foil includes, in the linking region, a linking portion that links the first connection region and the second connection region, the linking portion passing over the opening region of the at least one intermediate conductor foil and not overlapping the at least one intermediate conductor foil in plan view.

In the semiconductor module according to the above-described embodiment, the first conductor foil further includes, in the linking region, an additional linking portion overlapping, in the plan view, an end portion in a width direction orthogonal to a linking direction along which the first connection region and the second connection region in the linking region of the at least one intermediate conductor foil are linked to each other.

In the semiconductor module according to the above-described embodiment, a part of an opening region of the at least one intermediate conductor foil overlaps the electrode of the semiconductor element in plan view of the surface of the semiconductor element on which the electrode is formed.

In the semiconductor module according to the above-described embodiment, the first conductor foil and the second conductor foil have the same planar shape in plan view of the surface of the semiconductor element on which the electrode is formed.

The semiconductor module according to the above-described embodiment further includes an additional semiconductor element being disposed on the conductor pattern of the wiring board or another conductor pattern, the additional semiconductor element being connected to the conductor pattern or the other conductor pattern, and the other conductor being bonded to the second conductor spacer of the wiring member is an electrode of the additional semiconductor element.

In the semiconductor module according to the above-described embodiment, the second conductor spacer of the wiring member is electrically connected to a conductor pattern different from the conductor pattern of the wiring board.

The semiconductor module according to the above-described embodiment further includes a case member including a lead being electrically connected to the second conductor spacer of the wiring member.

In the semiconductor module according to the above-described embodiment, the wiring member further includes a third conductive spacer, and each of the plurality of conductor foils of the laminate includes a third connection region serving as a connection region with the third conductive spacer, and a second linking region between the first connection region and the third connection region, and each of the at least one intermediate conductor foil includes a second void formation portion that forms a void between the second linking region of the first conductor foil and the second linking region of the second conductor foil.

In the semiconductor module according to the above-described embodiment, the wiring board further includes a heat dissipation pattern being disposed on a surface of the insulating substrate, the surface being opposite the first surface.

The semiconductor module according to the above-described embodiment further includes a cooler being disposed on a surface of the wiring board, the surface being opposite a surface on which the semiconductor element is disposed, the cooler being bonded to the wiring board.

The vehicle according to the above-described embodiment includes the semiconductor module according to the above-described embodiment.

It is noted that the present invention is not limited to the above-described embodiments, and various changes, substitutions, and modifications may be made without departing from the spirit of the technical idea. Further, when the technical idea may be implemented in another method by the progress of the technology or another derived technology, the technical idea may be carried out by using the method thereof. Therefore, the claims cover all implementations that may be included within the scope of the technical idea.

As described above, the present invention has an effect that stress applied to a bonding surface between a wiring member connecting electrodes of a plurality of semiconductor elements in a semiconductor module and an electrode of the semiconductor element can be reduced, and a decrease in operation reliability of the semiconductor module due to variations in heat generation of the switching elements may be suppressed. Thus, the present invention is particularly useful for an industrial or on-vehicle semiconductor module used as a power conversion apparatus.

What is claimed is:

1. A semiconductor module, comprising:
a wiring board including an insulating substrate, and a conductor pattern disposed on a first surface of the insulating substrate;
a semiconductor element having an upper surface and a lower surface opposite to each other, the semiconductor element including an electrode on the upper surface thereof and being disposed on the conductor pattern of the wiring board, the lower surface of the semiconductor element being electrically connected to the conductor pattern;
a conductor disposed on the wiring board; and
a wiring member electrically connecting the conductor to the electrode of the semiconductor element, wherein
the wiring member includes
a first conductor spacer bonded to the electrode of the semiconductor element,
a second conductor spacer bonded to the conductor, and
a laminate including a plurality of conductor foils, the laminate connecting the first conductor spacer to the second conductor spacer, the plurality of conductor foils being disposed in a laminated manner at different distances from the upper surface of the semiconductor element in a thickness direction of the semiconductor element,
each of the plurality of conductor foils of the laminate includes
a first connection region to which the first conductor spacer is connected,
a second connection region to which the second conductor spacer is connected, and
a linking region between the first connection region and the second connection region,
the plurality of conductor foils includes
at least one intermediate conductor foil, and
a first conductor foil and a second conductor foil sandwiching the at least one intermediate conductor foil therebetween, and
each of the at least one intermediate conductor foil has a void formation area in which a void is formed in the thickness direction between the linking region of the first conductor foil and the linking region of the second conductor foil.

2. The semiconductor module according to claim 1, wherein the laminate has a tubular shape defined by the void formed in the void formation area of each of the at least one intermediate conductor foil, in each of the at least one intermediate conductor foil, the void extending at least from a boundary between the first connection region and the linking region to a boundary between the second connection region and the linking region.

3. The semiconductor module according to claim 1, wherein, in a plan view of the semiconductor element, each of the plurality of conductor foils of the laminate has a planar shape that does not overlap the others at least between each adjacent conductor foils that are adjacent to each other in the thickness direction among the plurality of conductor foils at the linking region, excluding end portions of the linking region that are opposite to each other in a linking direction from the first connection region to the second connection region.

4. The semiconductor module according to claim 3, wherein
the void formation area of each of the at least one intermediate conductor foil has an opening, thereby to form the void, and
the first conductor foil includes, in the linking region thereof, a linking portion that links the first connection region thereof to the second connection region thereof, the linking portion of the first conductor foil passing over the opening of the at least one intermediate conductor foil and not overlapping the at least one intermediate conductor foil in the plan view.

5. The semiconductor module according to claim 4, wherein the first conductor foil further includes an additional linking portion in the linking region thereof, the additional linking portion overlapping the at least one intermediate conductor foil in the plan view, at one of two end positions of the linking region of the at least one intermediate conductor foil that are opposite to each other in the width direction.

6. The semiconductor module according to claim 1, wherein a part of the void formation area of each of the at least one intermediate conductor foil overlaps the electrode of the semiconductor element in a plan view of the semiconductor element.

7. The semiconductor module according to claim 1, wherein the first conductor foil and the second conductor foil have the same planar shape in a plan view of the semiconductor element.

8. The semiconductor module according to claim 1, wherein
the conductor bonded to the second conductor spacer of the wiring member is an electrode of an additional semiconductor element, and
either the additional semiconductor element is disposed on the conductor pattern of the wiring board, or the wiring board further includes another conductor pattern thereon and the additional semiconductor element is disposed on the other conductor pattern.

9. The semiconductor module according to claim 1, wherein
the wiring board further includes another conductor pattern thereon, and
the second conductor spacer of the wiring member is electrically connected to the other conductor pattern.

10. The semiconductor module according to claim 1, further comprising a case member including a lead electrically connected to the second conductor spacer of the wiring member.

11. The semiconductor module according to claim 1, wherein
the wiring member further includes a third conductive spacer, and
each of the plurality of conductor foils of the laminate includes
a third connection region to which the third conductive spacer is connected, and
a second linking region connecting the first connection region to the third connection region, and
each of the at least one intermediate conductor foil includes a second void formation area in which a void is formed between, in the thickness direction, end positions of the second linking region of the first conductor foil and the second linking region of the second conductor foil.

12. The semiconductor module according to claim 1, wherein the wiring board further includes a heat dissipation pattern disposed on a second surface of the insulating substrate that is opposite to the first surface thereof.

13. The semiconductor module according to claim 1, further comprising a cooler disposed on the wiring board at a side thereof opposite to a side thereof where the semiconductor element is disposed, the cooler being bonded to the wiring board.

14. A vehicle comprising the semiconductor module according to claim 1.
